(19) United States
(12) Patent Application Publication
(10) Pub. No.: US 2008/0146011 A1
(43) Pub. Date: Jun. 19, 2008

(54) METHOD OF FORMING SELF-ASSEMBLED MONOLAYER ON ITO FILM

(75) Inventors: Young Soo Yoon, Gyeonggi-do (KR); Seung Hyun Jee, Gyeonggi-do (KR); Soo Ho Kim, Incheon (KR); Jae Hwan Ko, Gyeonggi-do (KR)

Correspondence Address: ADAM K. SACHAROFF;MUCH SHELIST FREED DENENBERG AMENT&RUBENSTEIN,PC, 191 N. WACKER DRIVE, SUITE 1800, CHICAGO, IL, 60606-1615, US

(73) Assignee: Konkuk University Industrial Cooperation Corp., Seoul (KR)

(21) Appl. No.: 11/697,395

(22) Filed: Apr. 6, 2007

(30) Foreign Application Priority Data
Dec. 14, 2006 (KR) 10-2006-0127984

(51) Int. Cl. H01L 21/20

(52) U.S. Cl. 438/584; 257/E21.533

(57) ABSTRACT

Disclosed is a method of modifying the surface of an ITO (Indium Tin Oxide; In₂O₃—SnO₂) film using new organic material to increase the properties of the ITO film. A method of forming a self-assembled monolayer on an ITO film to increase the work function of an ITO film for use in the transparent electrode of a display device and an ITO film having a self-assembled monolayer, manufactured using the above method, are provided. The ITO film having the self-assembled monolayer has an increased work function, and thus holes can be efficiently injected from the ITO to an organic layer. Thereby, ohmic contact between the organic layer and the electrode is realized, consequently improving the electrical properties of organic electronic devices.

### BACKGROUND OF THE INVENTION

1. Field of the Invention

The present invention relates, generally, to a method of modifying the surface of an ITO (Indium Tin Oxide; In₂O₃—SnO₂) film using new organic material to increase the properties of the ITO film, and more particularly, to a method of forming a self-assembled monolayer (SAM) on an ITO film so as to increase the work function of an ITO film for use in the transparent electrode of a display device.

2. Description of the Related Art

An SAM surface modification is realized in a manner such that an SAM is formed on the surface of a solid using material constituting the SAM. The SAM is strongly adsorbed on the surface of the solid, and has excellent thermal and chemical stability and superior physical strength.

Further, the SAM surface modification has a simple process and thus is mainly used in the field of nano-technology, and is easy to apply to a film having a large area compared to other methods.

Furthermore, the SAM surface modification is advantageous because the properties of the surface of a substrate can be changed without damaging the surface thereof physically or chemically.

An ITO film, which has high transmittance in the visible light range and excellent electrical conductivity, is presently used in a transparent electrode in the field of various flat display devices and electronic devices, such as solar cells.

In particular, an organic light emitting diode (OLED) or an organic thin film transistor (OTFT), which is regarded as a next-generation display, adopts an ITO film as the electrode thereof. However, when holes are injected to the hole injection layer of the OLED or the organic semiconductor from the ITO electrode, a large energy barrier is present between the ITO and the organic semiconductor. Hence, there is a need to increase the work function of the ITO to be equal to or higher than that of the organic compound constituting the hole injection layer or organic semiconductor, so that the energy barrier between the ITO anode (positive electrode) and the organic semiconductor is decreased as low as possible.

In order to decrease the energy barrier, the difference in ionization potential between the ITO electrode and an organic compound that can be used in the organic semiconductor should be reduced. The hole transport layer of the OLED or the organic semiconductor of the OTFT has a work function of 5e1˜5.4 eV, and the ITO has a work function of 4.5˜4.6 eV, from which a very large energy barrier can be confirmed to be present between the ITO electrode and the organic semiconductor.

With the goal of solving this problem, other materials having a high work function may be used. However, a transparent electrode having a high work function, capable of substituting for ITO, has not yet been developed, due to problems related to light transmittance, convenience of the process, and price.

In addition, although research into an increase in work function through surface modification using a UV or oxygen plasma dry process is being conducted, this research suffers because the extent of the increase in the work function is small and an expensive apparatus, such as a vacuum apparatus, must be used.

In addition, various attempts to increase the work function of metal using SAM surface modification have been made in foreign countries, however, in Korea, research thereon is still incomplete, and furthermore, there have been no reports of commercialization thereof.

Moreover, the international literature has reported the ITO having a work function increased by only about 0.3 eV using SAM, and there is no probability of ohmic contact with the organic semiconductor (J. Master. Chem. 2000, 10, 169-173).

### SUMMARY OF THE INVENTION

As a result of conducting research to increase the work function of ITO to the level of an organic semiconductor so as to efficiently inject holes between the electrode and the organic semiconductor when ITO is used in the transparent electrode of a display, the present inventors have found that ITO is basified, and is then subjected to surface modification using new organic material to thus form an SAM on the ITO film, thereby increasing the work function of the ITO film.

Therefore, an object of the present invention is to provide a method of forming an SAM on an ITO film, in order to increase the work function of the ITO film.

Another object of the present invention is to provide an ITO film having an increased work function, manufactured according to the above method.

In order to accomplish the above objects, the present invention provides a method of forming an SAM on an ITO film, thus increasing the work function of the ITO film.

### BRIEF DESCRIPTION OF THE DRAWINGS

FIG. 1 shows the process of forming the SAM on the ITO film, according to the present invention;

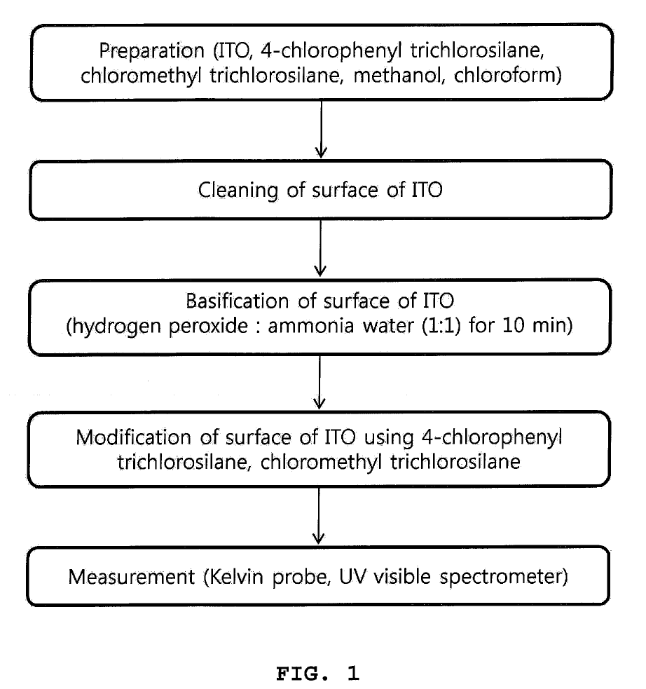

FIG. 2 shows the work function of the ITO film having the SAM, depending on the type of organic material; and

FIG. 3 shows the light transmittance of the ITO film having the SAM, depending on the type of organic material.

### DETAILED DESCRIPTION OF THE INVENTION

Hereinafter, a detailed description will be given of the present invention.

The present invention provides a method of forming an SAM on an ITO film, comprising the steps of (1) basifying the surface of the cleaned ITO film, in order to allow an SAM to be efficiently formed thereon, and (2) modifying the surface of the basified ITO film using an organic material.

In the present invention, the step (1) may be performed in a manner such that the ITO film is dipped in a solution comprising hydrogen peroxide and ammonia water, mixed at a volume ratio of 1:1, for 5-15 min, and preferably, for about 10 min, to thus induce the basification of the surface of the ITO film.

Further, in the step (2), the surface of the ITO film may be modified using the organic material, such as 4-chlorophenyl trichlorosilane (4-CPTS) or chloromethyl trichlorosilane (CMTS).

As such, the organic material is preferably used by dissolving it to a concentration of 20 mM in a solution comprising methanol and chloroform mixed at a volume ratio of 1:1, and the basified ITO film is dipped for 10 min therein.

In addition, the present invention provides an ITO film having an SAM, manufactured according to the above method.

Below the present invention is more specifically described through the following examples, which are set forth to illustrate, but are not to be construed as the limit of the present invention.

### EXAMPLE 1

### Preparation of ITO Film Having a High Work Function

An ITO film (available from Samsung, Korea) having a thickness of 400 Å and resistivity of 20-30 Q/□ was placed in an ultrasonic cleaning bath to remove impurities using isopropyl alcohol (IPA), and then the film was dried in an oven in a nitrogen atmosphere to thus eliminate the remainder of the IPA.

The cleaned ITO film was dipped for 10 min in a solution comprising hydrogen peroxide and ammonia water mixed at 1:1, thus basifying the surface of the film. Thereafter, the basified ITO film was dipped for 10 min in a solution of organic material for surface modification, such as 4-chlorophenyl trichlorosilane (4-CPTS) or chloromethyl trichlorosilane (CMTS), which was previously prepared to a concentration of 20 mM in a solution comprising methanol and chloroform mixed in an equal amount.

The ITO film thus manufactured was completely dried in an oven in a nitrogen atmosphere.

### EXAMPLE 2

### Measurement of Work Function and Light Transmittance of Surface Modified ITO Film

The work function of the surface modified ITO film, obtained in Example 1, was measured using a Kelvin probe.

Further, the light transmittance of the ITO film was measured using a UV visible spectrometer.

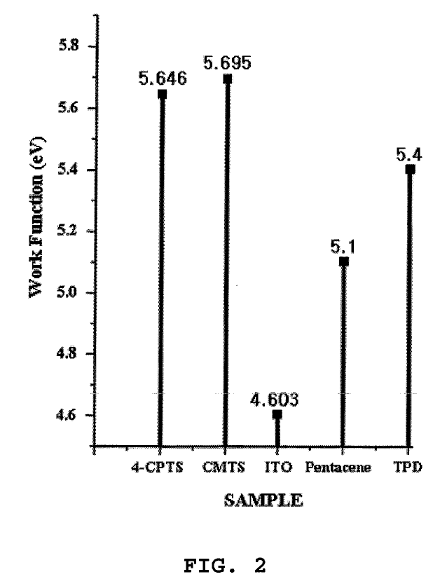

As shown in FIG. 2, the work function of the ITO film, which was not surface modified, was measured to be 4.603 eV, whereas the work function of the surface modified ITO film was measured to be 5.646 and 5.695 eV.

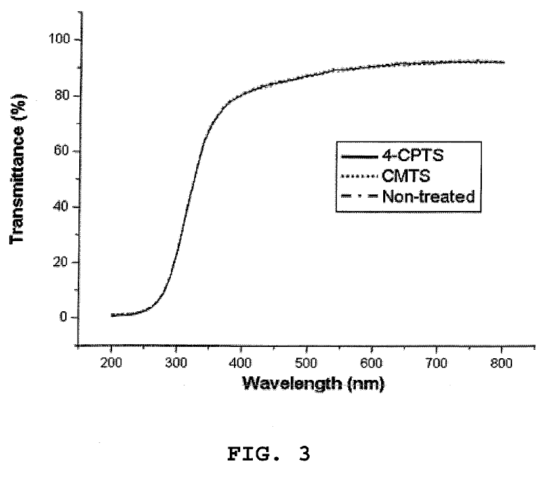

Almost no change in light transmittance within an experimental error range could be observed (FIG. 3).

As described hereinbefore, the present invention provides a method of forming an SAM on an ITO film and an ITO film having an increased work function owing to the formation of an SAM using the above method.

In particular, in consideration of the fact that the work function of the organic semiconductor or the hole injection portion of an OLED is 5.1˜5.4 eV, the energy barrier between the ITO and the organic layer can be decreased. The work function of the ITO film having the SAM according to the present invention is increased, such that holes can be efficiently injected from the ITO to the organic layer. Thereby, ohmic contact between the organic layer and the electrode is realized, consequently improving the electrical properties of organic electronic devices.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of forming a self-assembled monolayer on an ITO film, comprising steps of:
(1) basifying a surface of a cleaned ITO film to allow a self-assembled monolayer to be formed thereon; and
(2) modifying the surface of the basified ITO film using an organic material.

2. The method according to claim 1, wherein the step (1) is performed by dipping the ITO film for 5-15 min in a solution comprising hydrogen peroxide and ammonia water, mixed at a volume ratio of 1:1, thus inducing basification of the surface of the ITO film.

3. The method according to claim 1, wherein the organic material used in the modifying in the step (2) is selected from a group consisting of 4-chlorophenyl trichlorosilane (4-CPTS) and chloromethyl trichlorosilane (CMTS).

4. The method according to claim 3, wherein the organic material is used by dissolving it to a concentration of 20 mM in a solution comprising methanol and chloroform mixed at a volume ratio of 1:1, and the basified ITO film is dipped for 10 min therein.

5. An ITO film having a self-assembled monolayer, manufactured using the method of claim 1.
